(19) United States
(12) Patent Application Publication
(10) Pub. No.: US 2023/0021192 A1
(43) Pub. Date: Jan. 19, 2023

(54) ANTI-FUSE DEVICE WITH A CUP-SHAPED INSULATOR

(71) Applicant: Microchip Technology Incorporated, Chandler, AZ (US)

(72) Inventor: Yaojian Leng, Vancouver, WA (US)

(73) Assignee: Microchip Technology Incorporated, Chandler, AZ (US)

(21) Appl. No.: 17/862,693

(22) Filed: Jul. 12, 2022

Related U.S. Application Data
(60) Provisional application No. 63/222,367, filed on Jul. 15, 2021.

(51) Int. Cl. H01L 23/525; H01L 27/06

(52) U.S. Cl. CPC H01L 23/5252; H01L 27/0617

(57) ABSTRACT

An integrated circuit device includes an anti-fuse device. The anti-fuse device includes a cup-shaped bottom anti-fuse electrode, a cup-shaped anti-fuse insulator formed in an opening defined by the cup-shaped bottom anti-fuse electrode, and a top anti-fuse electrode formed in an opening defined by the cup-shaped anti-fuse insulator. A thickness of the cup-shaped anti-fuse insulator is less than 200 Å.

### RELATED APPLICATION

This application claims priority to commonly owned U.S. Provisional Patent Application No. 63/222,367 filed Jul. 15, 2021, the entire contents of which are hereby incorporated by reference for all purposes.

### TECHNICAL FIELD

The present disclosure relates to anti-fuses formed in integrated circuit (IC) structures, and more particularly to an anti-fuse formed by a damascene process.

### BACKGROUND

An anti-fuse is an electrically programmable two-terminal device. An anti-fuse has a high resistance in an un-programmed state, and a low resistance in a programmed state. Programming the anti-fuse converts the anti-fuse from high resistance state to a state with a permanent low resistance electrically conductive path. Typically the programming is performed when the voltage across the anti-fuse exceeds a certain level.

Anti-fuses are often used in FPGA (field programmable gate array) applications. Anti-fuse FPGAs may provide various advantages, e.g., as compared with SRAM (static random-access memory) or flash memory based FPGA. For example, anti-fuse FPGAs are nonvolatile and live at power-up, may exhibit shorter delays due to routing, may use less power than SRAM or flash memory, and may be more secure. Anti-fuse based FPGAs may be particularly suitable for radiation hardened application, e.g., space and military application.

One type of conventional anti-fuse includes a polysilicon layer separated from an n+ doped region by an oxide-nitride-oxide (ONO) dielectric layer. The anti-fuse is programmable between (a) an unprogrammed, high-resistance state and (b) a programmed state in which a conductive anti-fuse link is formed across the ONO dielectric layer, thereby defining a low-resistance state.

Typical anti-fuse FPGAs have various drawbacks or limitations. For example, conventional anti-fuses often require complex, non-standard fabrication processes, which may result in lower yield and slower technology evolution, e.g., as compared with SRAM FPGAs. As another example, conventional anti-fuse designs are often built between active and polysilicon regions, which may result in relatively high series resistance and low packing density (e.g., as compared with anti-fuses built on metal interconnect, and with multi-layer designs). As another example, some conventional anti-fuses are not effectively enclosed, such that a blown fuse, which may release energy that can damage nearby circuitry, may cause yield or reliability issues for surrounding integrated circuit structures.

### SUMMARY

Integrated anti-fuse devices and methods of forming integrated anti-fuse devices are provided. An integrated anti-fuse device may be formed between adjacent metal layers. The anti-fuse device may include an metal-insulator-metal (MIM) structure formed by a damascene process including forming a tub opening in a dielectric region, forming a cup-shaped bottom anti-fuse electrode in the tub opening, forming a cup-shaped anti-fuse insulator in an opening defined by the cup-shaped bottom anti-fuse electrode, and forming a top anti-fuse electrode in an opening defined by the cup-shaped anti-fuse insulator.

A thickness of the cup-shaped anti-fuse insulator may define or influence the breakdown voltage of the anti-fuse device, i.e., the voltage required to program the anti-fuse device. Thus, the cup-shaped anti-fuse insulator may be formed with a defined thickness that provides a desired breakdown voltage of the anti-fuse device. For example, the cup-shaped anti-fuse insulator may be formed with a pre-defined thickness that provides a breakdown voltage below 15V, below 10V, below 7V, or below 5V. In some examples, a thickness of the cup-shaped anti-fuse insulator is less than 200 Å, for example in the range of 50-175 Å, or in the range of 75-125 Å.

One aspect provides an integrated circuit device including an anti-fuse device. The anti-fuse device includes a cup-shaped bottom anti-fuse electrode, a cup-shaped anti-fuse insulator formed in an opening defined by the cup-shaped bottom anti-fuse electrode, and a top anti-fuse electrode formed in an opening defined by the cup-shaped anti-fuse insulator. A thickness of the cup-shaped anti-fuse insulator is less than 200 Å.

In some examples, the thickness of the cup-shaped anti-fuse insulator is in the range of 50-175 Å. In some examples, the thickness of the cup-shaped anti-fuse insulator is in the range of 75-125 Å.

In some examples, the anti-fuse device has a breakdown voltage below 15V. In some examples, the anti-fuse device has a breakdown voltage below 7V.

In some examples, the cup-shaped anti-fuse insulator comprises silicon oxide (SiO₂), oxide-nitride-oxide (ONO), nitride-oxide-nitride (NON), or aluminum oxide (Al₂O₃).

In some examples, the integrated circuit device includes a bottom anti-fuse electrode contact formed in a lower metal interconnect layer, wherein the bottom anti-fuse electrode contact is electrically connected to the cup-shaped bottom anti-fuse electrode, and a top anti-fuse electrode contact formed in an upper metal interconnect layer, wherein the top anti-fuse electrode contact is electrically connected to the top anti-fuse electrode.

In some examples, the integrated circuit device includes a transistor including a doped source region and a doped drain region, wherein the cup-shaped bottom anti-fuse electrode is electrically connected to a silicide region formed on the source region or a silicide region formed on the drain region of the transistor.

Another aspect provides an integrated circuit device including an interconnect structure and an anti-fuse device. The interconnect structure includes a lower interconnect element formed in a lower metal layer, an upper interconnect element formed in an upper metal layer, and an interconnect via formed in a dielectric region between the lower metal layer and the upper metal layer, the interconnect via electrically connecting the upper interconnect element to the lower interconnect element. The anti-fuse device includes a cup-shaped bottom anti-fuse electrode formed in the dielectric region, a cup-shaped anti-fuse insulator formed in an opening defined by the cup-shaped bottom anti-fuse electrode, and a top anti-fuse electrode formed in an opening defined by the cup-shaped anti-fuse insulator. A thickness of the cup-shaped anti-fuse insulator is less than 200 Å.

In some examples, the thickness of the cup-shaped anti-fuse insulator is in the range of 50-175 Å. In some examples, the thickness of the cup-shaped anti-fuse insulator is in the range of 75-125 Å.

In some examples, the anti-fuse device has a breakdown voltage below 15V. In some examples, the anti-fuse device has a breakdown voltage below 7V.

In some examples, the cup-shaped anti-fuse insulator comprises silicon oxide (SiO₂), oxide-nitride-oxide (ONO), nitride-oxide-nitride (NON), or aluminum oxide (Al₂O₃).

In some examples, the cup-shaped bottom anti-fuse electrode and the interconnect via are formed from the same conformal material.

In some examples, the lower interconnect element and the bottom anti-fuse electrode contact are formed in a lower metal interconnect layer, and the upper interconnect element and the top anti-fuse electrode contact are formed in an upper metal interconnect layer.

In some examples, the integrated circuit device comprises a transistor including a doped source region and a doped drain region, wherein the cup-shaped bottom anti-fuse electrode is electrically connected to a silicide region formed on the source region or a silicide region formed on the drain region of the transistor.

Another aspect provides a method of forming an anti-fuse device. The method includes forming a tub opening in a dielectric region; depositing a conformal metal over the dielectric region and extending into the tub opening to form a cup-shaped bottom anti-fuse electrode in the tub opening; depositing an insulator layer with a layer thickness of less than 200 Å over the conformal metal to define a cup-shaped anti-fuse insulator in an opening defined by the cup-shaped bottom anti-fuse electrode, the cup-shaped anti-fuse insulator including a laterally-extending anti-fuse insulator base and a vertically-extending anti-fuse insulator sidewall extending upwardly from the laterally-extending anti-fuse insulator base; depositing a top electrode metal over the insulator layer and extending into an opening defined by the cup-shaped anti-fuse insulator; and performing a planarization process to remove upper portions of the conformal metal, insulator layer, and top electrode metal outside the tub opening.

In some examples, the layer thickness is in the range of 50-175 Å.

In some examples, the layer thickness is in the range of 75-125 Å.

In some examples, the cup-shaped anti-fuse insulator comprises silicon oxide (SiO₂), oxide-nitride-oxide (ONO), nitride-oxide-nitride (NON), or aluminum oxide (Al₂O₃).

In some examples, the method includes depositing a dielectric barrier layer over a planarized upper surface defined by the planarization process, the dielectric barrier layer extending over a vertically-extending sidewall of the cup-shaped bottom anti-fuse electrode, the vertically-extending anti-fuse insulator sidewall, and the top anti-fuse electrode; depositing an upper dielectric layer over the dielectric barrier layer; etching the upper dielectric layer and the dielectric barrier to form a top anti-fuse electrode contact opening exposing an upper surface of the top anti-fuse electrode, wherein the dielectric barrier layer acts as an etch stop; and filling the top anti-fuse electrode contact opening to form a top anti-fuse electrode contact electrically connected to the top anti-fuse electrode.

In some examples, the anti-fuse device is formed without adding any photomask processes to a background integrated circuit fabrication process.

### BRIEF DESCRIPTION OF THE DRAWINGS

Example aspects of the present disclosure are described below in conjunction with the figures, in which:

FIG. 1A is a top down view and FIG. 1B is a side cross-sectional view of an example IC structure including an example anti-fuse device and an example interconnect structure, which may be formed concurrently, according to one example;

FIG. 2 shows a side cross-sectional view of the example anti-fuse device shown in FIGS. 1A and 1B;

FIGS. 3A-3I illustrate an example process for forming the integrated circuit structure shown in FIGS. 1A and 1B, including the example anti-fuse device and example interconnect structure;

FIG. 4 shows an example integrated circuit device including multiple anti-fuse devices formed at different depths in the integrated circuit device; and

FIG. 5 shows an example integrated circuit device including an example anti-fuse device and an example interconnect structure formed between a silicided active region including a MOSFET transistor and a first metal interconnect layer.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

Integrated anti-fuse devices and methods of forming integrated anti-fuse devices are provided. An integrated anti-fuse device may be formed between adjacent metal layers. The anti-fuse device may include a MIM structure including a cup-shaped bottom anti-fuse electrode formed in a tub opening in a dielectric region, a cup-shaped anti-fuse insulator formed in an opening defined by the cup-shaped bottom anti-fuse electrode, and a top anti-fuse electrode formed in an opening defined by the cup-shaped anti-fuse insulator.

A thickness of the anti-fuse insulator may define or influence the breakdown voltage of the anti-fuse device. Thus, the anti-fuse insulator may be formed with a defined thickness that provides a desired breakdown voltage of the anti-fuse device. For example, the cup-shaped anti-fuse insulator may be formed with a pre-defined thickness that provides a breakdown voltage below 15V, below 10V, below 7V, or below 5V. In some examples, a thickness of the cup-shaped anti-fuse insulator is less than 200 Å, for example in the range of 50-175 Å, or in the range of 75-125 Å.

As used herein, a “metal layer” may comprise any metal or metalized layer or layers, including:

(a) a metal interconnect layer, e.g., comprising copper, aluminum or other metal formed by a damascene process or by a subtractive patterning process (e.g., deposition, patterning, and etching of a metal layer), or

(b) a silicided active region including a number of silicided structures (structures having a metal silicide layer formed thereon), for example a silicided source region, drain region, or polysilicon gate of a MOSFET.

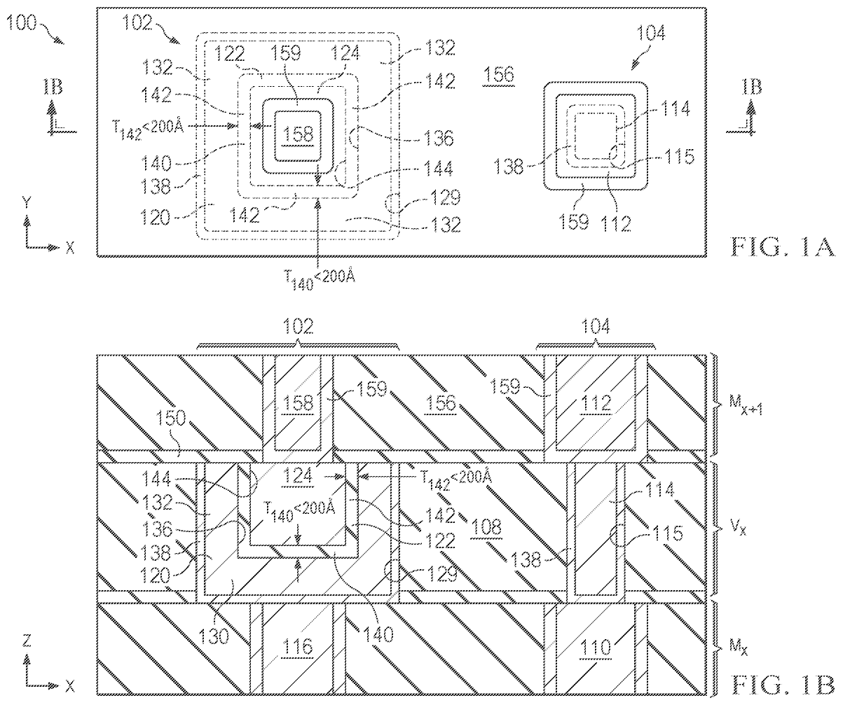

For example, as discussed below with respect to FIGS. 1A-1B, FIGS. 3A-3I, and FIG. 4, an anti-fuse device may be constructed between two adjacent metal interconnect layers Mₓ and Mₓ₊₁ at any depth in an integrated circuit device. As another example, as discussed below with respect to FIG. 5, an anti-fuse device may be constructed over a silicided active region, for example on a silicon transistor having metal silicide layers formed on selected transistor components, and below a first metal interconnect layer (often referred to as Metal-1); in such an example, the silicided active region defines the lower metal layer Mₓ where x=0 (i.e., M₀) and the first metal interconnect layer (Metal-1) defines the upper metal layer Mₓ₊₁ (i.e., M₁).

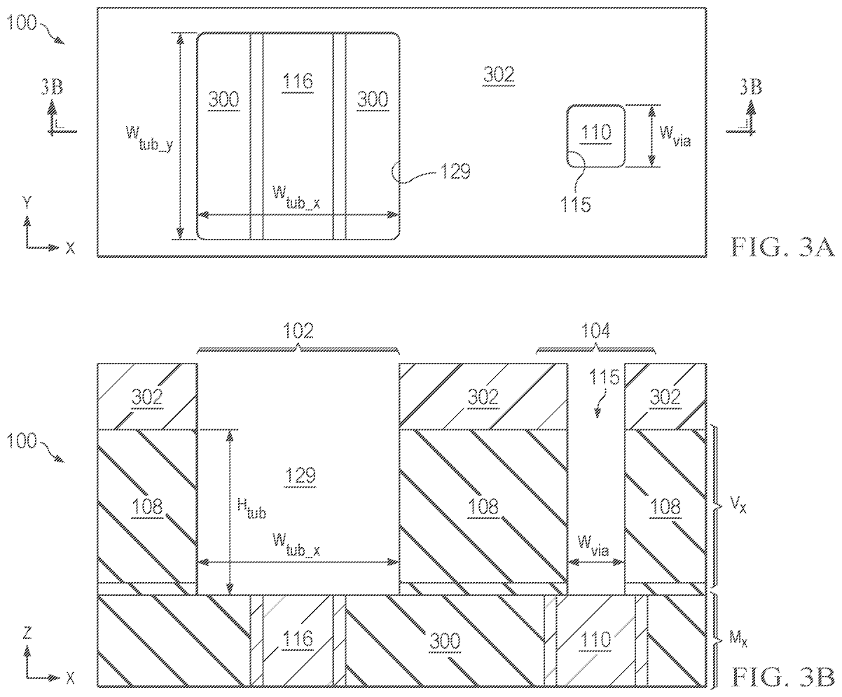

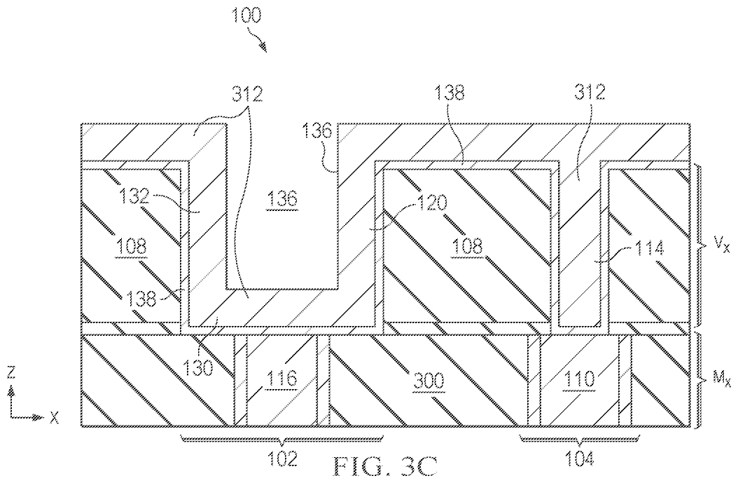

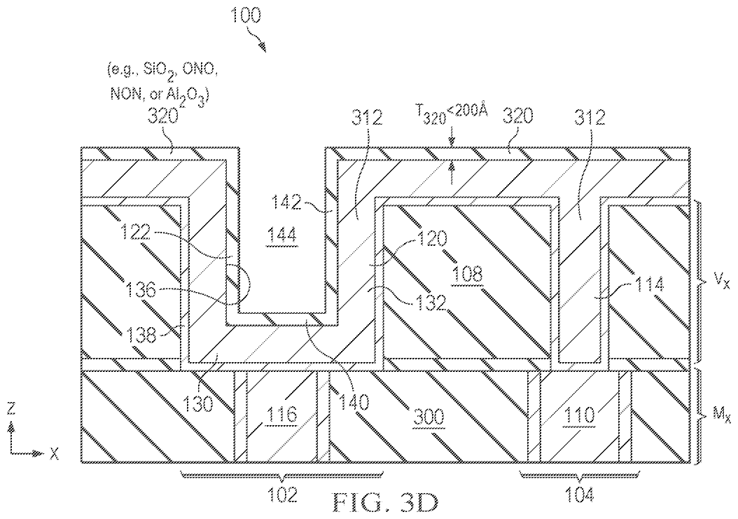

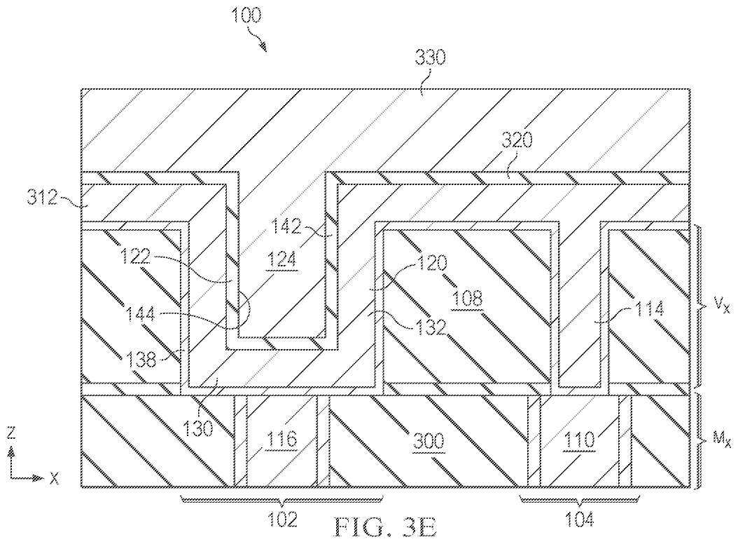

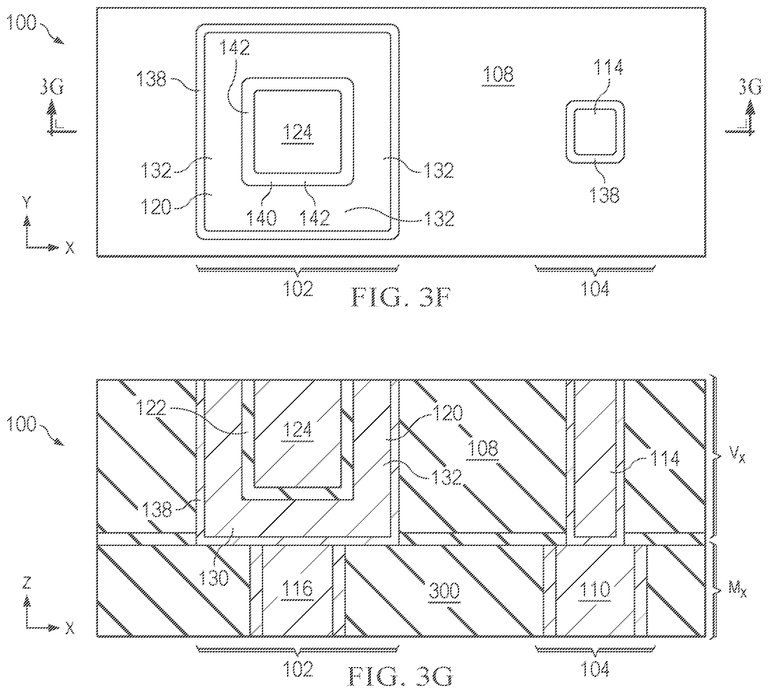

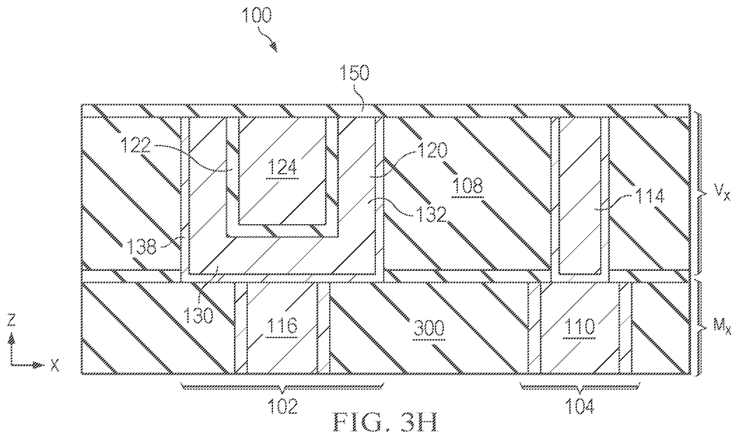

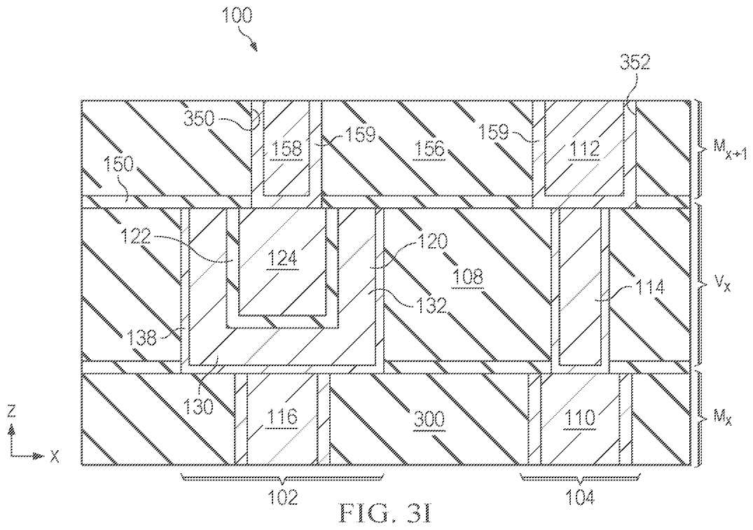

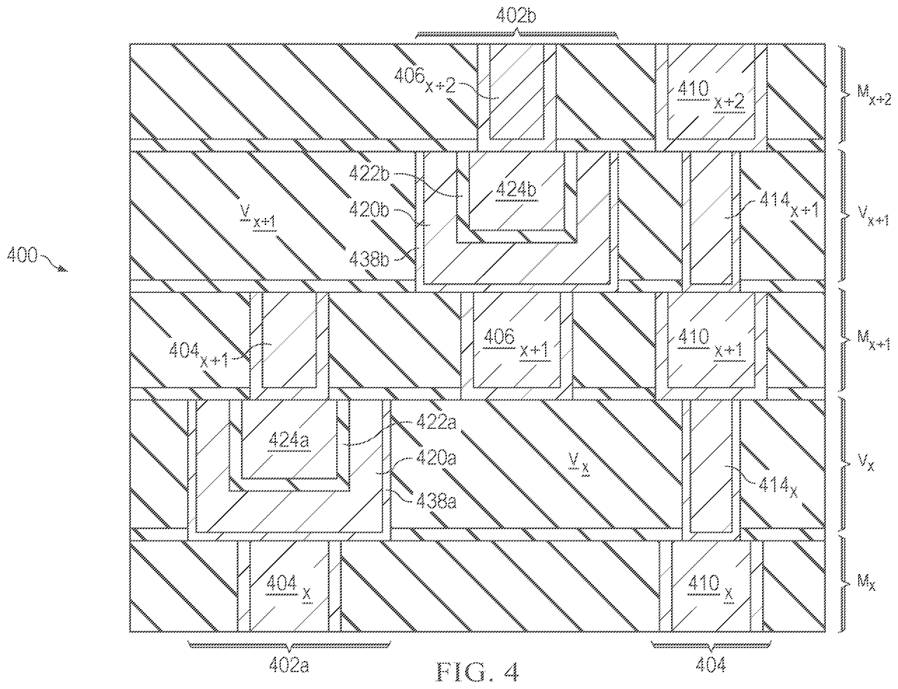

In some examples, an anti-fuse device may be formed concurrently with certain interconnect structures, e.g., interconnect via, separate from the anti-fuse device. For example, as shown in the method of FIGS. 3A-3I discussed below, the cup-shaped bottom anti-fuse electrode of an anti-fuse device may be formed concurrently with interconnect via(s), by deposition of a conformal metal layer (e.g., tungsten) into respective openings for the cup-shaped bottom anti-fuse electrode and the interconnect via(s).

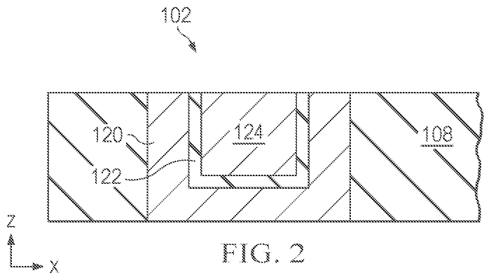

In other examples, an anti-fuse device may be formed independently from, i.e., not concurrently with, interconnect structures. For example, FIG. 2 shows an example anti-fuse device that may be formed independently from interconnect structures, or alternatively may be formed concurrently with interconnect structures, e.g., interconnect via.

As discussed below with reference to FIGS. 3A-3I, an anti-fuse device may be constructed using a damascene process and without adding any mask operations to the background integrated circuit fabrication process.

FIGS. 1A and 1B show an example integrated circuit device 100 including an example anti-fuse device 102 and an example interconnect structure 104. In particular, FIG. 1A shows a top view of the integrated circuit device 100, and FIG. 1B shows a side cross-sectional view of the integrated circuit device 100 through cut line 1B-1B shown in FIG. 1A. As shown, the example anti-fuse device 102 has a three-dimensional (3D) metal/insulator/metal (MIM) structure formed between a lower metal layer Mₓ and an upper layer Mₓ₊₁. In the example shown in FIGS. 1A-1B, the lower metal layer Mₓ and upper layer Mₓ₊₁ represent two adjacent metal interconnect layers, such that the anti-fuse device 102 is formed in a via layer Vₓ between the two adjacent metal interconnect layers Mₓ and Mₓ₊₁. In other examples, e.g., as shown in FIG. 5 discussed below, the anti-fuse device may be formed between a silicided active region (including one or more silicon-based transistors including silicided structures) and a first metal interconnect layer (often referred to as Metal-1).

As shown in FIGS. 1A-1B, the example interconnect structure 104 includes a lower interconnect element 110 formed in lower metal layer Mₓ, an upper interconnect element 112 formed in upper metal layer Mₓ₊₁, and at least one interconnect via 114 formed in via layer Vₓ and electrically connecting the upper interconnect element 112 to the lower interconnect element 110.

Each of the lower interconnect element 110 and upper interconnect element 112 may comprise a wire or other laterally elongated structure (e.g., elongated in the y-axis direction), or a discrete pad (e.g., having a square, circular, substantially square, or substantially circular shape in the x-y plane), or any other suitable shape and structure.

The example anti-fuse device 102 is formed in a tub opening 129 formed in a dielectric region 108 in the via layer Vₓ. The anti-fuse device 102 includes a cup-shaped bottom anti-fuse electrode 120, a cup-shaped anti-fuse insulator 122 formed in an opening 136 defined by the cup-shaped bottom anti-fuse electrode 120, and a top anti-fuse electrode 124 formed in an opening 144 defined by the cup-shaped anti-fuse insulator 122.

As discussed below with reference to the method shown in FIGS. 3A-3I, the cup-shaped bottom anti-fuse electrode 120 may formed concurrently with interconnect via 114 by depositing a conformal metal into the tub opening 129 and a via opening 115 formed in dielectric region 108. In some examples, the conformal metal forming the cup-shaped bottom anti-fuse electrode 120 and interconnect via 114 may comprise tungsten, cobalt, aluminum, or other conformal metal. In some examples, a liner 138, e.g., comprising titanium nitride (TiN), is deposited in tub opening 129 and via opening 115 prior to the conformal metal, to improve adhesion between the conformal metal and dielectric region 108.

The cup-shaped bottom anti-fuse electrode 120 includes (a) a laterally-extending bottom anti-fuse electrode base 130 formed over and electrically connected to an underlying bottom anti-fuse electrode contact 116 and (b) a vertically-extending bottom anti-fuse electrode sidewall 132 extending upwardly from the laterally-extending bottom anti-fuse electrode base 130. In the illustrated example, laterally-extending bottom anti-fuse electrode base 130 has a rectangular shape, and the vertically-extending bottom anti-fuse electrode sidewall 132 has a closed-loop rectangular shape (as shown in FIG. 1A) extending upwardly from the lateral perimeter sides of the laterally-extending bottom anti-fuse electrode base 130.

The cup-shaped anti-fuse insulator 122 is formed in the opening 136 defined by the cup-shaped bottom anti-fuse electrode 120, and includes a laterally-extending insulator base 140 formed on the bottom anti-fuse electrode base 130, and a vertically-extending insulator sidewall 142 extending upwardly from the laterally-extending insulator base 140, wherein the vertically-extending insulator sidewall 142 is formed on the vertically-extending bottom anti-fuse electrode sidewall 132.

A thickness of the cup-shaped anti-fuse insulator 122 may define or influence the breakdown voltage of the anti-fuse device 102. Thus, in some examples the cup-shaped anti-fuse insulator 122 may be formed with a pre-defined thickness that provides a pre-specified breakdown voltage of the anti-fuse device 102. For example, the cup-shaped anti-fuse insulator 122 may be formed with a defined thickness that provides a breakdown voltage of the anti-fuse device 102 of below 15V, below 10V, below 7V, or below 5V. As used herein, the thickness of the cup-shaped anti-fuse insulator refers to the smallest thickness of (a) a smallest vertical thickness T₁₄₀ of the laterally-extending insulator base 140 and (b) a smallest lateral thickness T₁₄₂ of the vertically-extending insulator sidewall 142.

In some examples, a thickness of the cup-shaped anti-fuse insulator 122 is less than 200 Å. For example, a thickness of the cup-shaped anti-fuse insulator 122 may be in the range of 50-175 Å, or in the range of 75-125 Å, depending on the particular example.

In some examples, the cup-shaped anti-fuse insulator 122 comprises silicon oxide (SiO₂), an ONO layer stack or NON layer stack, or aluminum oxide (Al₂O₃).

The top anti-fuse electrode 124 of the example anti-fuse device 102 is formed in opening 144 defined by the cup-shaped anti-fuse insulator 122. In some examples, the top anti-fuse electrode 124 may comprise titanium nitride (TiN), titanium (Ti), tungsten (W), or a combination thereof. Thus, in some examples, both the bottom anti-fuse electrode 120 and the top anti-fuse electrode 124 may be formed from refractory metals (e.g., W, TiN, or Ti), which may reduce or eliminate the generation of hillocks, which may provide a tight program voltage window (e.g., in the range of a few volts without outliers) and thereby avoid uncontrolled (unintended) low-voltage programming of the anti-fuse.

A dielectric barrier layer 150 may be formed over the top anti-fuse electrode 124, vertically-extending insulator sidewall 142, vertically-extending bottom anti-fuse electrode sidewall 132, and interconnect via 114. In some examples, the dielectric barrier layer 150 may comprise silicon nitride (SiN) or silicon carbide (SiC) with a thickness in the range of 300-700 Å. The dielectric barrier layer 150 may act as a diffusion barrier (e.g., to prevent or reduce diffusion from the top anti-fuse electrode 124, e.g., formed from copper or other diffusive material) and seal a top side of the anti-fuse device 102, which may cooperate with the cup-shaped bottom anti-fuse electrode 120 (e.g., formed from tungsten) to define a sealed enclosure for the anti-fuse device 102 to contain the physical effects of breaking the fuse link, often referred to as “blowing the fuse,” and thereby prevent or reduce collateral damage to nearby structures in the integrated circuit device 100 caused by the associated energy release.

The upper metal layer (Mₓ₊₁) formed over the via layer Vₓ (in which the anti-fuse device 102 and interconnect via 114 are constructed) includes a top anti-fuse electrode contact 158 electrically connected to the top anti-fuse electrode 124 and upper interconnect element 112 electrically connected to the interconnect via 114. In some embodiments, the top anti-fuse electrode contact 158 and upper interconnect element 112 are formed using a damascene process, e.g., using copper, tungsten, or aluminum. For example, top anti-fuse electrode contact 158 and upper interconnect element 112 may comprise copper elements formed over a barrier layer 159, e.g., a TaN/Ta bilayer. In some examples, in addition to sealing the top side of the anti-fuse device 102 as discussed above, the dielectric barrier layer 150 may act as an etch stop during construction of the upper metal layer Mₓ₊₁, e.g., during an etch process forming respective openings for the upper interconnect element 158 and top anti-fuse electrode contact 112.

In some examples, the anti-fuse device 102 is formed concurrently with the interconnect structure 104. For example, as discussed below, the cup-shaped bottom anti-fuse electrode 120 may be formed concurrently with interconnect via 114. As noted above, in other examples the anti-fuse device 102 may be formed independently from (not concurrently with) interconnect structure 104.

FIG. 2 shows a side cross-sectional view of the example anti-fuse device 102 described above. As discussed above, anti-fuse device 102 may include cup-shaped bottom anti-fuse electrode 120 formed in dielectric region 108, cup-shaped anti-fuse insulator 122 formed in opening defined by cup-shaped bottom anti-fuse electrode 120, and top anti-fuse electrode 124 formed in opening defined by cup-shaped anti-fuse insulator 122. In some examples, a thickness of the cup-shaped anti-fuse insulator 122 is less than 200 Å. For example, a thickness of the cup-shaped anti-fuse insulator 122 may be in the range of 50-175 Å, or in the range of 75-125 Å, depending on the particular example. As described above, in some examples, anti-fuse device 102 may be formed independently from interconnect structures, e.g., interconnect via, or alternatively may be formed concurrently with interconnect structures, e.g., interconnect via formed in dielectric region 108.

FIGS. 3A-3I illustrate an example process for forming the integrated circuit device 100 shown in FIG. 1, including the example anti-fuse device 102 and example interconnect structure 104. Those skilled in the art will recognize that the same process, without reference to interconnect structure 104, can be used to form the integrated anti-fuse device 102 shown in FIG. 2.

First, as shown in FIG. 3A (top view) and FIG. 3B (cross-sectional side view through line 3B-3B shown in FIG. 3A), a dielectric region 108 is formed over lower metal layer Mₓ, lower metal layer Mₓ including lower interconnect element 110 and bottom anti-fuse electrode contact 116. Dielectric region 108 may comprise an inter-metal dielectric (IMD) region, e.g., comprising silicon oxide, fluorinated silicate glass (FSG), organosilicate glass (OSG), or porous OSG. Lower interconnect element 110 and bottom anti-fuse electrode contact 116 may comprise copper elements formed by a damascene process. Lower interconnect element 110 and bottom anti-fuse electrode contact 116 may comprise a respective wire or other laterally elongated structure (e.g., elongated in the y-direction), or a discrete pad (e.g., having a square, circular, substantially square or substantially circular shape in the x-y plane), or any other suitable shape and structure.

A photoresist layer 302 is deposited and patterned to form photoresist openings, and the underlying dielectric region 108 is etched through the photoresist openings to form tub opening 129 for the formation of the anti-fuse device 102 and via opening 115 in dielectric region 108. Via opening 115 may have a square, circular, or other suitable shape from a top view (x-y plane), with a width (or diameter or critical dimension (CD)) Wᵥᵢₐ in both the x-direction and y-direction in the range of 0.1-0.35 μm, or for example.

In contrast, the tub opening 129 may have a substantially greater width W_{tub_x} in the x-direction and/or width W_{tub_y} in the y-direction than via opening 115. Thus, the tub opening 129 may be referred to as a “tub” opening. The shape and dimensions of the tub opening 129 may be selected based on various parameters, e.g., for effective manufacturing and/or desired performance characteristics of the anti-fuse device 102 being formed. In one example, tub opening 129 may have a square or rectangular shape in the x-y plane. In other examples, tub opening 129 may have a circular or oval shape in the x-y plane.

As noted above, a width of tub opening 129 in the x-direction (W_{tub_x}), y-direction (W_{tub_y}), or both the x-direction and y-direction (W_{tub_x} and W_{tub_y}) may be substantially larger than both the width Wᵥᵢₐ of via opening 115 in the x-direction and width Wᵥᵢₐ of via opening 115 in the y-direction. For example, in some examples, each width of W_{tub_x} and W_{tub_y} of tub opening 129 is at least twice as large as the width Wᵥᵢₐ of via opening 115. In particular examples, each width W_{tub_x} and W_{tub_y} of tub opening 129 is at least five time as large as the width Wᵥᵢₐ of via opening 115. Each width of tub opening 129 (W_{tub_x} and W_{tub_y}) may be sufficient to allow construction of the anti-fuse device 102 within the tub opening 129 by a damascene process, for example allowing the construction of cup-shaped bottom anti-fuse electrode 120, cup-shaped anti-fuse insulator 122 formed in opening 136 of the cup-shaped bottom anti-fuse electrode 120, and top anti-fuse electrode 124 formed in opening 144 of the cup-shaped anti-fuse insulator 122. In some examples, W_{tub_x} and W_{tub_y} are each in the range of 0.5-10 μm, for example in the range of 0.5-2 μm.

Further, tub opening 129 may be formed with a height-to-width aspect ratio of less than or equal to 2.0 in both the x-direction and y-direction, e.g., to allow effective filling of the tub opening 129 by conformal materials. For example, tub opening 129 may be formed with aspect ratios H_{tub}/W_{tub_x} and H_{tub}/W_{tub_y} each in the range of 0.1-2.0, for example in the range of 0.5-2.0. In some examples, aspect ratios H_{tub}/W_{tub_x} and H_{tub}/W_{tub_y} are each less than or equal to 1.5, e.g., for effective filling of tub opening 129 by conformal materials, e.g., tungsten, cobalt, or aluminum. For example, tub opening 129 may be formed with aspect ratios H_{tub}/W_{tub_x} and H_{tub}/W_{tub_y} each in the range of 0.5-1.5, or more particularly in the range of 0.8-1.2.

As shown in FIG. 3C, photoresist layer 302 is removed, and a liner 138, e.g., comprising TiN, is deposited over dielectric region 108 and extends down into tub opening 129 and via opening 115. The liner 138 may be deposited using a physical vapor deposition (PVD) process or a chemical vapor deposition (CVD) process. In some examples, liner 138 may have a thickness in the range of 50-500 Å.

A conformal metal 312 may be deposited over the liner 138 and extend down into the tub opening 129 and into the via opening 115. As shown, the deposited conformal metal 312 (a) fills via opening 115 to form the interconnect via 114 and (b) covers the interior surfaces of the tub opening 129 to form the cup-shaped bottom anti-fuse electrode 120 of the anti-fuse device 102, which defines an opening 136. As discussed above, the cup-shaped bottom anti-fuse electrode 120 includes a vertically-extending bottom anti-fuse electrode sidewall 132 extending upwardly from the laterally-extending bottom anti-fuse electrode cup base 130, and in one example vertically-extending bottom anti-fuse electrode sidewall 132 extends upwardly from lateral sides, or perimeter, of laterally-extending bottom anti-fuse electrode cup base 130. In one example, conformal metal 312 comprises tungsten deposited with a thickness in the range of 1000-5000 Å. In other examples, conformal metal 312 may comprise cobalt, aluminum, or other conformal metal. Conformal metal 312 may be deposited by a conformal chemical vapor deposition (CVD) process or other suitable deposition process. Liner 138 (e.g., comprising TiN) may increase or enhance an adhesion of the conformal metal 312 to the interior surfaces of the tub opening 129, including vertical sidewall surfaces of tub opening 129, to facilitate the formation of cup-shaped bottom anti-fuse electrode 120.

As shown in FIG. 3D, an insulator layer 320 is deposited over conformal metal 312 and extends down into opening 136 defined by the cup-shaped bottom anti-fuse electrode 120 to define the cup-shaped anti-fuse insulator 122 in opening 136. Cup-shaped anti-fuse insulator 122 includes laterally-extending insulator base 140 and vertically-extending insulator sidewall 142 extending upwardly from lateral sides of the laterally-extending insulator base 140. Cup-shaped anti-fuse insulator 122 defines an opening 144.

In some examples, insulator layer 320 (including cup-shaped anti-fuse insulator 122) is deposited with a layer thickness T₃₂₀ of less than 200 Å, for example in the range of 50-175 Å or some examples in the range of 75-125 Å. In some examples, insulator layer 320 comprises (a) silicon oxide (SiO₂), an oxide-nitride-oxide (ONO) layer stack, or a nitride-oxide-nitride (NON) layer stack deposited by plasma-enhanced chemical vapor deposition (PECVD) or other suitable deposition process, or (b) aluminum oxide (Al₂O₃) deposited by atomic layer deposition (ALD) or other suitable deposition process, or (c) other suitable insulator material.

As shown in FIG. 3E, a top electrode metal 330 may be deposited over insulator layer 320 and extends down into opening 144 defined by cup-shaped anti-fuse insulator 122, to define the top anti-fuse electrode 124 in opening 144. Top electrode metal 330 may comprise titanium nitride (TiN), titanium (Ti), tungsten (W), tantalum, tantalum nitride, copper, or a combination thereof, and may be deposited by a PVD process and with a sufficient thickness to fill opening 144.

As shown in FIG. 3F (top view) and FIG. 3G (cross-sectional side view through line 3G-3G shown in FIG. 3F), a planarization process may be performed to remove upper portions of the conformal metal 312, insulator layer 320, and top electrode metal 330 outside tub opening 129 and via opening 115, leaving cup-shaped bottom anti-fuse electrode 120, cup-shaped anti-fuse insulator 122, and top anti-fuse electrode 124 in tub opening 129. In some examples the planarization process comprises a chemical mechanical planarization (CMP) process. The planarization process effectively planarizes the top surfaces of the cup-shaped bottom anti-fuse electrode 120, cup-shaped anti-fuse insulator 122, top anti-fuse electrode 124, via 114 and surrounding dielectric region 108.

According to the process described above the anti-fuse device 102 may be formed by a damascene process including (a) depositing the conformal metal 312, insulator layer 320, and top electrode metal 330 over dielectric region 108 and extending down into the tub opening 129, and (b) a planarization process to remove upper portions of the conformal metal 312, insulator layer 320, and top electrode metal 330 outside (above) the tub opening 129. The planarization process may be suitable for a wide variety of electrode materials for conformal metal 312 and/or top electrode metal 330, including for example W, WO₃, Al₂O₃, TiW, Ta, TaN, or Cu, without limitation.

As shown in FIG. 3H, dielectric barrier layer 150 may be deposited on the integrated circuit device 100, to fully enclose and seal the exposed top surfaces of the anti-fuse device 102. In some examples, dielectric barrier layer 150 may comprise a dielectric material such as silicon nitride (SiN) or silicon carbide (SiC) with a thickness in the range of 300-1000 Å, for example in the range of 400-600 Å. Dielectric barrier layer 150 and cup-shaped bottom anti-fuse electrode 120 may collectively define a sealed enclosure for anti-fuse device 102, which sealed enclosure may contain the physical forces caused by a blown fuse situation and thereby prevent or reduce collateral damage to nearby structures in the integrated circuit device 100. The dielectric barrier layer 150 may also act as a diffusion barrier to prevent or reduce metal diffusion from the top anti-fuse electrode 124, e.g., formed from copper or other diffusive material.

As shown in FIG. 3I, upper metal layer Mₓ₊₁, including top anti-fuse electrode contact 158 and upper interconnect element 112, may be formed above via layer Vₓ (including anti-fuse device 102 and interconnect via 114) for example using a damascene process. In one example, upper metal layer Mₓ₊₁ comprises a copper interconnect layer formed by a copper damascene process.

To form upper metal layer Mₓ₊₁, a dielectric layer 156 is first deposited over dielectric barrier layer 150. In some examples, dielectric layer 156 may comprise silicon oxide (SiO₂), FSG (FluoroSilicate Glass), OSG (OrganoSilicate Glass), or porous OSG. Dielectric layer 156 may be patterned and etched to form a top anti-fuse electrode contact opening 350 above the top anti-fuse electrode 124, and an interconnect opening 352 (e.g., trench opening) above the via 114, with the etch first stops on, then proceeds through dielectric barrier layer 150 through top anti-fuse electrode contact opening 350 and interconnect opening 352. Dielectric barrier layer 150 may act as an etch stop layer for the formation of the top anti-fuse electrode contact opening 350 and interconnect opening 352 to improve the etch process margin.

A barrier layer 159 (e.g., a TaN/Ta bilayer) and a copper seed layer may be deposited over the dielectric layer 156 and extend down into the etched top anti-fuse electrode contact opening 350 and interconnect opening 352. A copper electro-plating process may then be performed, which fills the top anti-fuse electrode contact opening 350 and interconnect opening 352 with copper. A copper anneal may be performed, followed by a copper CMP process to remove portions of the copper above the dielectric layer openings 350 and 352, thereby defining the top anti-fuse electrode contact 158 electrically connected to the top anti-fuse electrode 124, and an upper interconnect element 112 electrically connected to the via 114.

After forming the upper metal layer Mₓ₊₁ as discussed above, the process may continue to construct additional interconnect structures, e.g., by constructing additional metal layers separated by respective dielectric layers.

As discussed above, in some examples an integrated anti-fuse device can be built between two interconnect layers Mₓ and Mₓ₊₁, or between an active region and a first metal interconnect layer (Metal-1). In other examples, multiple anti-fuse devices may be formed at different depths in integrated circuit devices, which may provide a higher packing density of anti-fuse devices.

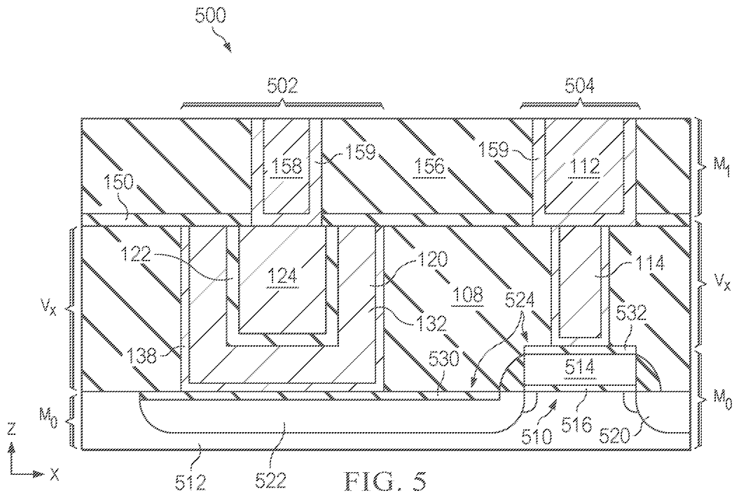

FIG. 4 shows an example IC structure 400 including two example anti-fuse devices 402a and 402b formed at different depths in the integrated circuit structure 400, along with an example interconnect structure 404. First anti-fuse device 402a is formed in a first via layer Vₓ between metal interconnect layers Mₓ and Mₓ₊₁, and second anti-fuse device 402b is formed in a second via layer Vₓ₊₁ between metal interconnect layers Mₓ₊₁ and Mₓ₊₂. First anti-fuse device 402a is conductively connected between a lower metal contact 404ₓ formed in metal interconnect layer Mₓ and an upper metal contact 404ₓ₊₁ formed in metal interconnect layer Mₓ₊₁, and second anti-fuse device 402b is conductively connected between a lower metal contact 406ₓ₊₁ formed in metal interconnect layer Mₓ₊₁ and an upper metal contact 406ₓ₊₂ formed in metal interconnect layer Mₓ₊₂.

Example first and second anti-fuse devices 402a and 402b may be similar to example anti-fuse device 102 discussed above, e.g., formed from similar materials as disclosed above and formed according to the example process shown in FIGS. 3A-3I. Thus, first anti-fuse device 402a includes a cup-shaped lower electrode 420a formed over a liner 438a (similar to liner 138 discussed above), a cup-shaped anti-fuse insulator 422a formed in an opening defined by the cup-shaped lower electrode 420a, and a top anti-fuse electrode 424a formed in an opening defined by the cup-shaped anti-fuse insulator 422a. Similarly, second anti-fuse device 402b includes a cup-shaped lower electrode 420b formed over a liner 438b, a cup-shaped anti-fuse insulator 422b formed in an opening defined by the cup-shaped lower electrode 420b, and a top anti-fuse electrode 424b formed in an opening defined by the cup-shaped anti-fuse insulator 422b.

The example interconnect structure 404 includes metal interconnect elements 410ₓ, 410ₓ₊₁, and 410ₓ₊₂, along with interconnect vias 414ₓ and 414ₓ₊₁. In this example, first anti-fuse device 402a may be formed concurrently with interconnect via 414ₓ—for example, the cup-shaped bottom anti-fuse electrode 420a and interconnect via 414ₓ may be formed concurrently by depositing tungsten or other conformal material in respective openings in a dielectric material 408ₓ formed in first via layer Vₓ. Similarly, anti-fuse device 402b may be formed concurrently with interconnect via 414ₓ₊₁—for example, the cup-shaped bottom anti-fuse electrode 420b and interconnect via 414ₓ₊₁ may be formed concurrently by depositing tungsten or other conformal material in respective openings in a dielectric material 408ₓ₊₁ formed in second via layer Vₓ₊₁.

FIG. 5 shows an example integrated circuit device 500 including an example anti-fuse device 502 and an example interconnect structure 504. Anti-fuse device 502 may be similar to anti-fuse device 102 discussed above. However, unlike the example shown in FIGS. 1A-1B in which anti-fuse device 102 is formed between two adjacent metal interconnect layers Mₓ and Mₓ₊₁, anti-fuse device 502 is formed between (a) a silicided active region M₀ (i.e., Mₓ where x=0) including silicided structures (e.g., silicided transistor components) and (b) a first metal interconnect layer M₁ (i.e., Mₓ₊₁ where x=0), often referred to as Metal-1.

As shown in FIG. 5, the silicided active region M₀ includes a metal-oxide-semiconductor field-effect transistor (MOSFET) 510 formed on a silicon substrate 512. The MOSFET 510 may include a polysilicon gate 514 formed over and separated from the silicon substrate 512 by gate oxide layer 516, and a doped source region 520 and doped drain region 522 formed in the silicon substrate 512. In this example, the polysilicon gate 514 and the doped drain region 522 comprise silicided structures 524. In particular, a metal silicide layer 530 is formed on a top surface of doped drain region 522, and a metal silicide layer 532 is formed on a top surface of the polysilicon gate 514. Metal silicide layers 530 and 532 may comprise any suitable metal silicide layer, for example titanium silicide (TiSi2), cobalt silicide (CoSi2), or nickel silicide (NiSi), having a thickness in the range of 100-300 Å or other suitable thickness. For the purposes of the present disclosure, metal silicide layers 530 and 532 define metal structures, such that the silicided active region M₀ can be considered as a metal layer.

In the example shown in FIG. 5, anti-fuse device 502 is formed on the metal silicide layer 530 on top of the doped drain region 522 to provide a conductive connection between the anti-fuse device 502 and the doped drain region 522. Anti-fuse device 502 is contacted from above by the top anti-fuse electrode contact 158, as discussed above. Further, via 114 (also referred to as a contact) is formed on the metal silicide layer 532 on top of the polysilicon gate 514 to provide conductive connection between the polysilicon gate 514 and the upper interconnect element 112. The top anti-fuse electrode contact 158 and upper interconnect element 112 comprise metal elements formed in the first metal interconnect layer M₁, e.g., by a damascene process.

1. An integrated circuit device, comprising:
an anti-fuse device including:
a cup-shaped bottom anti-fuse electrode formed in a dielectric region;
a cup-shaped anti-fuse insulator formed in an opening defined by the cup-shaped bottom anti-fuse electrode;
wherein a thickness of the cup-shaped anti-fuse insulator is less than 200 Å; and
a top anti-fuse electrode formed in an opening defined by the cup-shaped anti-fuse insulator.

2. The integrated circuit device of claim 1, wherein the thickness of the cup-shaped anti-fuse insulator is in the range of 50-175 Å.

3. The integrated circuit device of claim 1, wherein the thickness of the cup-shaped anti-fuse insulator is in the range of 75-125 Å.

4. The integrated circuit device of claim 1, wherein the anti-fuse device has a breakdown voltage below 15V.

5. The integrated circuit device of claim 1, wherein the anti-fuse device has a breakdown voltage below 7V.

6. The integrated circuit device of claim 1, wherein the cup-shaped anti-fuse insulator comprises silicon oxide (SiO₂), oxide-nitride-oxide (ONO), nitride-oxide-nitride (NON), or aluminum oxide (Al₂O₃).

7. The integrated circuit device of claim 1, comprising:
a bottom anti-fuse electrode contact formed in a lower metal interconnect layer, wherein the bottom anti-fuse electrode contact is electrically connected to the cup-shaped bottom anti-fuse electrode; and
a top anti-fuse electrode contact formed in an upper metal interconnect layer, wherein the top anti-fuse electrode contact is electrically connected to the top anti-fuse electrode.

8. The integrated circuit device of claim 1, comprising a transistor including a doped source region and a doped drain region;
wherein the cup-shaped bottom anti-fuse electrode is electrically connected to a silicide region formed on the source region or a silicide region formed on the drain region of the transistor.

9. An integrated circuit device, comprising:
an interconnect structure including:
a lower interconnect element formed in a lower metal layer;
an upper interconnect element formed in an upper metal layer; and
an interconnect via formed in a dielectric region between the lower metal layer and the upper metal layer, the interconnect via electrically connecting the upper interconnect element to the lower interconnect element; and
an anti-fuse device including:
a cup-shaped bottom anti-fuse electrode formed in the dielectric region;
a cup-shaped anti-fuse insulator formed in an opening defined by the cup-shaped bottom anti-fuse electrode;
wherein a thickness of the cup-shaped anti-fuse insulator is less than 200 Å; and
a top anti-fuse electrode formed in an opening defined by the cup-shaped anti-fuse insulator.

10. The integrated circuit device of claim 9, wherein the thickness of the cup-shaped anti-fuse insulator is in the range of 50-175 Å.

11. The integrated circuit device of claim 9, wherein the thickness of the cup-shaped anti-fuse insulator is in the range of 75-125 Å.

12. The integrated circuit device of claim 9, wherein the anti-fuse device has a breakdown voltage below 15V.

13. The integrated circuit device of claim 9, wherein the cup-shaped anti-fuse insulator comprises silicon oxide (SiO₂), oxide-nitride-oxide (ONO), nitride-oxide-nitride (NON), or aluminum oxide (Al₂O₃).

14. The integrated circuit device of claim 9, wherein:
the lower interconnect element and the bottom anti-fuse electrode contact are formed in a lower metal interconnect layer; and
the upper interconnect element and the top anti-fuse electrode contact are formed in an upper metal interconnect layer.

15. The integrated circuit device of claim 9, comprising a transistor including a doped source region and a doped drain region;
wherein the cup-shaped bottom anti-fuse electrode is electrically connected to a silicide region formed on the source region or a silicide region formed on the drain region of the transistor.

16. A method of forming an anti-fuse device, the method comprising:
forming a tub opening in a dielectric region;
depositing a conformal metal over the dielectric region and extending into the tub opening to form a cup-shaped bottom anti-fuse electrode in the tub opening;
depositing an insulator layer with a layer thickness of less than 200 Å over the conformal metal to define a cup-shaped anti-fuse insulator in an opening defined by the cup-shaped bottom anti-fuse electrode, the cup-shaped anti-fuse insulator including a laterally-extending anti-fuse insulator base and a vertically-extending anti-fuse insulator sidewall extending upwardly from the laterally-extending anti-fuse insulator base;
depositing a top electrode metal over the insulator layer and extending into an opening defined by the cup-shaped anti-fuse insulator; and
performing a planarization process to remove upper portions of the conformal metal, insulator layer, and top electrode metal outside the tub opening.

17. The method of claim 16, comprising depositing the insulator layer with the layer thickness in the range of 50-175 Å.

18. The method of claim 16, comprising depositing the insulator layer with the layer thickness in the range of 75-125 Å.

19. The method of claim 16, comprising:
depositing a dielectric barrier layer over a planarized upper surface defined by the planarization process, the dielectric barrier layer extending over a vertically-extending sidewall of the cup-shaped bottom anti-fuse electrode, the vertically-extending anti-fuse insulator sidewall, and the top anti-fuse electrode;
depositing an upper dielectric layer over the dielectric barrier layer;
etching the upper dielectric layer and the dielectric barrier to form a top anti-fuse electrode contact opening exposing an upper surface of the top anti-fuse electrode, wherein the dielectric barrier layer acts as an etch stop; and
filling the top anti-fuse electrode contact opening to form a top anti-fuse electrode contact electrically connected to the top anti-fuse electrode.

20. The method of claim 16, wherein the anti-fuse device is formed without adding any photomask processes to a background integrated circuit fabrication process.
